(19) United States
(12) Patent Application Publication
(10) Pub. No.: US 2025/0149336 A1
(43) Pub. Date: May 8, 2025

(54) PHOTORESIST COMPOSITION AND METHOD OF MANUFACTURING INTEGRATED CIRCUIT DEVICE USING THE SAME

(71) Applicant: Samsung Electronics Co., Ltd., Suwon-si (KR)

(72) Inventors: Yonghoon MOON, Suwon-si (KR); Sukkoo HONG, Suwon-si (KR); Seungchul KWON, Suwon-si (KR); Sungan DO, Suwon-si (KR); Hana KIM, Suwon-si (KR)

(73) Assignee: Samsung Electronics Co., Ltd., Suwon-si (KR)

(21) Appl. No.: 18/827,120

(22) Filed: Sep. 6, 2024

(30) Foreign Application Priority Data
Nov. 2, 2023 (KR) 10-2023-0150274

(51) Int. Cl. H01L 21/027; G03F 7/00; G03F 7/004; G03F 7/027; G03F 7/20; H01L 21/3213

(52) U.S. Cl. CPC H01L 21/0274; G03F 7/0042; G03F 7/027; G03F 7/2022; G03F 7/70016; G03F 7/70025; G03F 7/70033; G03F 7/7005; G03F 7/7045; H01L 21/32139

(57) ABSTRACT

A photoresist composition includes an organometallic compound including at least one metal-ligand bond and having an absorbance to first light, the at least one metal-ligand bond including a metal core and at least one organic ligand bonded to the metal core, a photosensitive additive having an absorbance to second light having a longer wavelength than the first light, and a solvent. A method of manufacturing an integrated circuit device includes forming a photoresist film on a substrate based on using the photoresist composition, exposing a first area of the photoresist film to the first light, exposing an entire area of the photoresist film to the second light, and forming a network of metal structures in the first area based on baking the photoresist film.

### CROSS-REFERENCE TO RELATED APPLICATION

This application is based on and claims priority under 35 U.S.C. § 119 to Korean Patent Application No. 10-2023-0150274, filed on Nov. 2, 2023, in the Korean Intellectual Property Office, the disclosure of which is incorporated by reference herein in its entirety.

### BACKGROUND

The inventive concepts relate to photoresist compositions and methods of manufacturing an integrated circuit (IC) device using the same, and more particularly, to photoresist compositions including a metal and methods of manufacturing an IC device using the photoresist composition.

In recent years, the downscaling of semiconductor devices has rapidly progressed due to the development of electronic technology. Thus, a photolithography process which is advantageous for forming fine patterns may be required.

Conventional chemically amplified resist (CAR) uses a mechanism in which the solubility of an organic polymer resin to a developer varies in an exposed area due to a chain reaction caused by photons. The CAR may have problems such as the deterioration of a critical dimension (CD) distribution due to acid diffusion caused by the chain reaction. A typical organic polymer may have a low absorbance to short-wavelength light, thus making it difficult to improve sensitivity.

### SUMMARY

Some example embodiments of the inventive concepts provide a photoresist composition which may provide excellent etching resistance and resolution at a small dose by efficiently using energy in a photolithography process for manufacturing an integrated circuit (IC) device.

Some example embodiments of the inventive concepts provide a method of manufacturing an IC device by using the photoresist composition which may provide excellent etching resistance and resolution at a small dose by efficiently using energy in a photolithography process for manufacturing an IC device, so that the dimensional precision of a pattern to be formed may be improved.

According to some example embodiments of the inventive concepts, a photoresist composition may include an organometallic compound including at least one metal-ligand bond, the organometallic compound having an absorbance to first light, and the at least one metal-ligand bond including a metal core and at least one organic ligand bonded to the metal core, a photosensitive additive having an absorbance to second light having a longer wavelength than the first light, and a solvent.

According to some example embodiments of the inventive concepts, a photoresist composition may include an organometallic compound including at least one metal-ligand bond, the organometallic compound being configured to dissociate the at least one metal-ligand bond by absorbing first light having a wavelength of about 10 nm to about 300 nm, and the at least one metal-ligand bond including a metal core and at least one organic ligand bonded to the metal core, a photosensitive additive excited by absorbing second light having a wavelength of about 300 nm to about 450 nm to induce an oxidation-reduction reaction of the organometallic compound, and a solvent.

According to some example embodiments of the inventive concepts, a method of manufacturing an integrated circuit (IC) device may include forming a photoresist film on a substrate by using a photoresist composition including an organometallic compound and a photosensitive additive, the organometallic compound including a metal core and at least one metal-ligand bond bonded to the metal core, wherein the organometallic compound has a sensitivity to first light, and the photosensitive additive has a sensitivity to second light, exposing a first area to the first light, wherein the first area is a portion of the photoresist film, exposing an entire area of the photoresist film to the second light, forming a network of metal structures in the first area by baking the photoresist film, and forming a photoresist pattern by developing the photoresist film in which the network of the metal structures is formed, the photoresist pattern including the network of the metal structures, wherein the first light has a wavelength of about 10 nm to about 300 nm, and the second light has a wavelength of about 300 nm to about 450 nm.

### BRIEF DESCRIPTION OF THE DRAWINGS

Example embodiments will be more clearly understood from the following detailed description taken in conjunction with the accompanying drawings in which:

FIG. 1 is a flowchart of a method of manufacturing an integrated circuit (IC) device, according to some example embodiments;

FIGS. 2A, 2B, 2C, 2D, 2E, and 2F are cross-sectional views showing a process sequence of a method of manufacturing an IC device, according to some example embodiments; and

FIG. 3 is a graph showing measurements of remaining film thicknesses, which were obtained by irradiating extreme ultraviolet (EUV) light at different doses after a certain amount of i-line was irradiated to photoresist films formed using compositions according to Example 1 and Comparative Example 1, according to some example embodiments.

### DETAILED DESCRIPTION

Hereinafter, some example embodiments will be described in detail with reference to the accompanying drawings. The same reference numerals are used to denote the same elements in the drawings, and repeated descriptions thereof are omitted.

Further, since sizes and thicknesses of portions, regions, members, units, layers, films, etc. illustrated in the accompanying drawings may be arbitrarily illustrated for better understanding and convenience of explanation, the present inventive concepts are not limited to the illustrated sizes and thicknesses. In the drawings, thicknesses of portions, regions, members, units, layers, films, etc. may be enlarged or exaggerated for convenience of explanation.

It will be understood that when a component such as a layer, film, region, or substrate is referred to as being “on” another component, it may be directly on other components or an intervening component may also be present. In contrast, when a component is referred to as being “directly on” another component, there is no intervening component present. Further, when a component is referred to as being “on” or “above” a reference component, a component may be positioned on or below the reference component, and does not necessarily be “on” or “above” the reference component toward an opposite direction of gravity.

In addition, unless explicitly described to the contrary, the word “comprise”, and variations such as “comprises” or “comprising”, will be understood to imply the inclusion of stated elements but not the exclusion of any other elements.

Further, throughout the specification, a phrase “on a plane”, “in a plane”, “on a plan view”, or “in a plan view” may indicate a case where a portion is viewed from above or a top portion, and a phrase “on a cross-section” or “in a cross-section” may indicate when a cross-section taken along a vertical direction is viewed from a side.

The use of the term “the” and similar demonstratives may correspond to both the singular and the plural. Operations constituting methods may be performed in any suitable order unless otherwise indicated herein or otherwise clearly contradicted by context and are not necessarily limited to the stated order.

The use of all illustrations or illustrative terms in some example embodiments is simply to describe the technical ideas in detail, and the scope of the present inventive concepts is not limited by the illustrations or illustrative terms unless they are limited by claims.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same. While the term “same,” “equal” or “identical” may be used in description of some example embodiments, it should be understood that some imprecisions may exist. Thus, when one element is referred to as being the same as another element, it should be understood that an element or a value is the same as another element within a desired manufacturing or operational tolerance range (e.g., ±10%).

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values or shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

A photoresist composition according to some example embodiments may include an organometallic compound, a photosensitive additive, and a solvent. According to some example embodiments, the organometallic compound may have an absorbance to first light having a relatively short wavelength, and the photosensitive additive may have an absorbance to second light having a relatively longer wavelength than that of the first light.

According to some example embodiments, the organometallic compound may include a metal core and at least one organic ligand bonded to the metal core. For example, a bond between the metal core and the at least one organic ligand in the organometallic compound may be a coordinate bond or a covalent bond.

In the photoresist composition according to some example embodiments, the organometallic compound may absorb the first light when exposed (e.g., based on being exposed, in response to being exposed, etc.) to the first light. Absorbed energy may cause a mutual reaction between the metal core and the at least one ligand bonded to the metal core, and thus, a bond between the metal core and the at least one organic ligand may be dissociated. The at least one organic ligand dissociated from the metal core and the metal core that has lost the at least one organic ligand may each form a reactive group or radicals. The reactive group and the radicals may participate in a cross-linking reaction in an exposure process using the first light, a later-described exposure process using the second light, and/or a bake process.

According to some example embodiments, the first light may have a wavelength of about 10 nm to about 300 nm. The first light may be selected from, for example, a krypton fluoride (KrF) excimer laser (248 nm), an argon fluoride (ArF) excimer laser (193 nm), a fluorine (F₂) excimer laser (157 nm), an Ar₂ excimer laser (126 nm), and an extreme ultraviolet (EUV) laser (13.5 nm), wherein “laser” and “laser beam” may be used interchangeably. In some example embodiments, a dose (e.g., energy density) of the first light may be about 10 mJ/cm² to about 200 mJ/cm².

In the photoresist composition according to some example embodiments, the metal core included in the organometallic compound may include at least one metal element. The at least one metal element may have the form of a metal atom, a metallic ion, a metal compound, a metal alloy, or any combination thereof. The metal compound may include a metal oxide, a metal nitride, a metal oxynitride, a metal silicide, a metal carbide, or any combination thereof. In some example embodiments, the metal core may include at least one metal element selected from tin (Sn), antimony (Sb), indium (In), bismuth (Bi), silver (Ag), tellurium (Te), gold (Au), lead (Pb), zinc (Zn), titanium (Ti), hafnium (Hf), zirconium (Zr), aluminum (Al), vanadium (V), chromium (Cr), cobalt (Co), nickel (Ni), copper (Cu), gallium (Ga), manganese (Mn), strontium (Sr), tungsten (W), cadmium (Cd), molybdenum (Mo), tantalum (Ta), niobium (Nb), cesium (Cs), barium (Ba), lanthanum (La), cerium (Ce), and iron (Fe), but the inventive concepts are not limited thereto.

In some example embodiments, the organometallic compound may be represented by Formula 1:

M(X¹¹)ₐ(X¹²)_{b}(R¹¹)_{c}(R¹²)_{d} [Formula 1]

Wherein, in Formula 1, M denotes Sn, Sb, In, Bi, Ag, Te, Au, Pb, Zn, Ti, Hf, Zr, Al, V, Cr, Co, Ni, Cu, Ga, Mn, Sr, W, Cd, Mo, Ta, Nb, Cs, Ba, La, Ce, or Fe, each of X¹¹ and X¹² is independently a substituted or unsubstituted C1 to C30 aliphatic hydrocarbon group or a substituted or unsubstituted C6 to C30 aromatic hydrocarbon group, which includes at least one hetero atom of sulfur (S), oxygen (O), and nitrogen (N) and is coordinately bonded to M (e.g., each of X¹¹ and X¹² is independently a group that is a substituted or unsubstituted C1 to C30 aliphatic hydrocarbon group or a substituted or unsubstituted C6 to C30 aromatic hydrocarbon group, wherein the group includes at least one heteroatom and is coordinately bonded to M), each of R¹¹ and R¹² is independently a substituted or unsubstituted C1 to C30 aliphatic hydrocarbon group or a substituted or unsubstituted C6 to C30 aromatic hydrocarbon group, which is covalently bonded to M (e.g., each of R¹¹ and R¹² is independently group that is a substituted or unsubstituted C1 to C30 aliphatic hydrocarbon group or a substituted or unsubstituted C6 to C30 aromatic hydrocarbon group, wherein the group covalently bonded to M), and each of a, b, c, and d is independently an integer of 0 to 4, c+d is an integer of 1 or more (e.g., 1 to 4), and a+b+c+d is an integer of 4 or less (e.g., 1, 2, 3, or 4).

In some example embodiments, each of X¹¹ and X¹² is independently R²¹—O−*, R²² to C(═O)—O—*, R²³−O to C(═O)—*, R²⁴—O to C(═O)—O—*, R²⁵—N(R²⁶)—*, R²⁷—S—*, R²⁸—S(═O)₂—*, or R²⁹—S(═O)₂—O—*. Herein, * denotes a bonding site with M, and each of R²¹, R²², R²³, R²⁴, R²⁵, R²⁶, R²⁷, R²⁸, and R²⁹ is independently hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C1 to C30 alkoxy group, a substituted or unsubstituted C6 to C30 aryl group, a substituted or unsubstituted C2 to C30 heteroaryl group, a substituted or unsubstituted C7 to C30 arylalkyl group, or a substituted or unsubstituted phenyl group.

As used herein, unless otherwise defined, the term “substituted” may refer to substituting at least one hydrogen bonded to carbon with a substituent or substituting at least one carbon atom with a heteroelement-containing group. The substituent may include, for example, a halogen element, a hydroxyl group, an aldehyde group, a carboxyl group, an amino group, a cyano group, an isocyanate group, a thiol group, a sulfonic acid group, a phosphoric acid group, salts thereof, C1 to C20 alkyl, C1 to C20 cycloalkyl, C2 to C20 alkenyl, C1 to C20 alkoxy, C2 to C20 alkenoxy, C6 to C30 aryl, C6 to C30 aryloxy, C7 to C30 alkylaryl, or C7 to C30 alkylaryloxy group. The heteroelement-containing group may include, for example, —O—, to C(═O)—O—, —O to C(═O)—, to C(═O)—, —O to C(═O)—O—, to C(═O)—NH—, —NH—, —S—, —S(═O)₂—, or —S(═O)₂—O—.

In some example embodiments, each of X¹¹ and X¹² may be end-capped with reactive groups. For instance, the reactive group may include a hydroxide group, a carboxylate group, a sulfonate group, and a phosphonate group, without being limited thereto.

In some example embodiments, at least one of X¹¹ or X¹² may include a polydentate ligand. The polydentate ligand may be a bidentate ligand including two coordinatable atoms, or a tridentate ligand including three coordinatable atoms, without being limited thereto. For example, the polydentate ligand may have a structure selected from quinoline, β-diketonate, ethylenediaminetetraacetic acid (EDTA), 2,2′-bis(diphenylphosphino)-1,1′-binaphthyl (BINAP), 2,2′-ethylenebis(nitrilomethylidene)diphenol (salen), norbornene dicarboxylic acid, camphoric acid, and derivatives thereof, without being limited thereto.

In some example embodiments, each of R¹¹ and R¹² may be independently a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C1 to C30 alkoxy group, a substituted or unsubstituted C6 to/C30 aryl group, a substituted or unsubstituted C2 to C30 heteroaryl group, or a substituted or unsubstituted C7 to C30 arylalkyl group.

In some example embodiments, each of R¹¹ and R¹² may include a C1 to C10 straight-chain aliphatic hydrocarbon group. In some example embodiments, at least one of R¹¹ or R¹² may be end-capped with reactive groups. For example, the reactive group may include a hydroxide group, a carboxylate group, a sulfonate group, and a phosphonate group, without being limited thereto.

In some example embodiments, each of R¹¹ and R¹² may include an aromatic ring, a heterocyclic aromatic ring, or any combination thereof. The aromatic ring may include a monocyclic aromatic ring (e.g., benzene); a heteroaryl group (e.g., pyridine, pyrimidine, and thiophene); and a condensed aryl group (e.g., quinolone, isoquinoline, naphthalene, anthracene, and phenanthrene. Each of the heteroaryl group and the condensed aryl group may include at least one heteroatom selected from an O atom, a S atom, and an N atom.

In some example embodiments, each of R¹¹ and R¹² may include at least one selected from the following structural units. In the following structures, * denotes a bonding site with M.

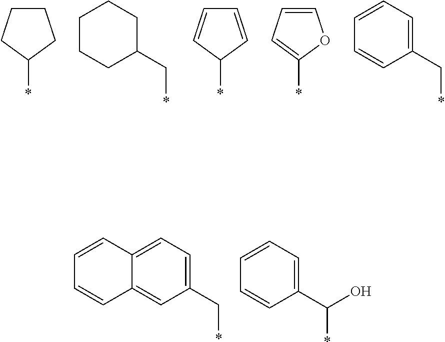

In some example embodiments, in Formula 1, at least one selected from X¹¹, X¹², R¹¹, and R¹² may include at least one selected from the following structural units.

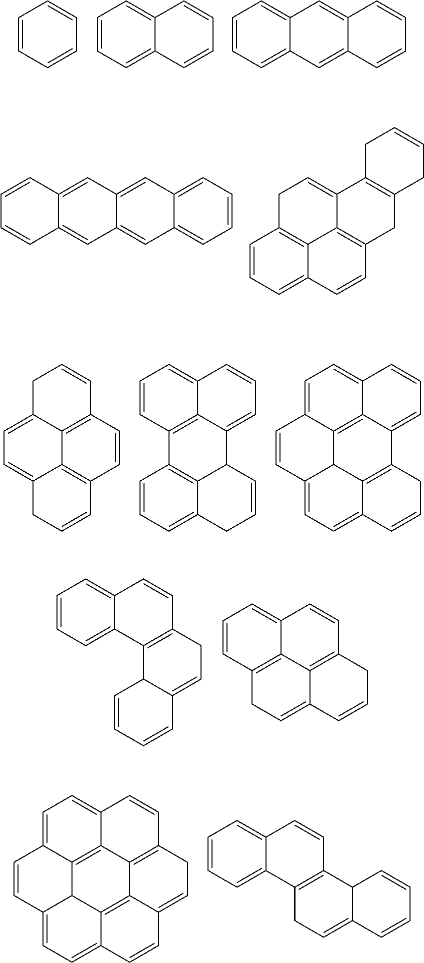

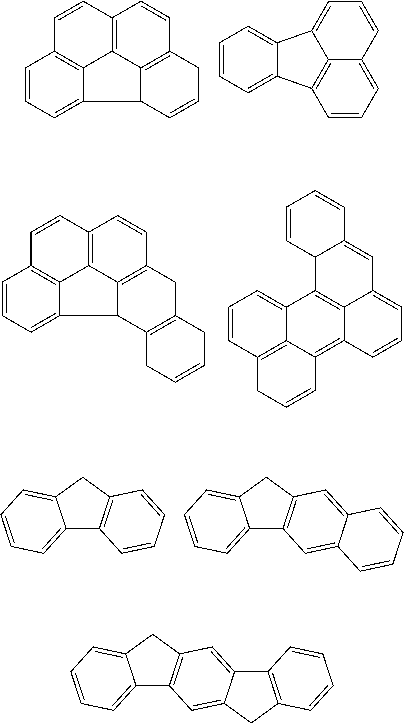

In some example embodiments, when the organometallic compound is exposed to the first light, the organometallic compound may absorb the first light, and some organic ligands of X¹¹, X¹², R¹¹, and R¹² of Formula 1 may be dissociated from the metal core M. Accordingly, in some example embodiments, the organic compound may be configured to, based on being exposed to the first light, absorb the first light to cause at least some organic ligands of X¹¹, X¹², R¹¹, and R¹² of Formula 1 to be dissociated from the metal core M.

In some example embodiments, the organometallic compound may be contained (e.g., contained in the photoresist composition) at a content of about 0.1% to about 20% by weight, based on a total weight of the photoresist composition, without being limited thereto. In some example embodiments, the organometallic compound may be contained at a content of about 0.1% to about 15% by weight, about 0.1% to about 10% by weight, or about 0.1% to about 5% by weight. When a content of the organometallic compound in the photoresist composition is excessively high (e.g., greater than about 20% by weight), there is a risk that a cross-linking reaction will be concentrated on the exposed surface, thus deteriorating pattern stability. Conversely, when the content of the organometallic compound in the photoresist composition is excessively low (e.g., less than about 0.1% by weight), the organometallic compound may not form a sufficient amount of reactive groups and/or radicals, which reduce pattern precision.

In the photoresist composition according to some example embodiments, the photosensitive additive may be excited by absorbing the second light when exposed (e.g., based on being exposed) to the second light. For instance, the photosensitive additive may have an absorbance to the second light. The excited photosensitive additive may cause an oxidation-reduction reaction with the organometallic compound to dissociate the at least one organic ligand of the organometallic compound from the metal core or induce a bond between a first organic ligand of a first organometallic compound and a second organic ligand of a second organometallic compound.

For example, after the organic ligand is deprotected from the metal core, a hydroxyl (—OH) functional group may be generated at a site of the organometallic compound, from which the organic ligand is dissociated. A condensation reaction of the hydroxyl (—OH) functional group may be induced due to a bake process, which is a subsequent process of the process of exposing the photoresist film. As a result, a cross-linked structure (e.g., an M-O-M cross-linked structure) including a plurality of metals M may be formed. For example, a cross-linked structure (e.g., an M-R—X-M cross-linked structure, an M-R—R-M cross-linked structure, or an M-X—X-M cross-linked structure) including a plurality of metals M may be formed due to a cross-linking reaction between organic ligands of adjacent organometallic compounds. Here, R may be a derivative of R¹¹ or R¹² of Formula 1, and X may be a derivative of X¹¹ or X¹² of Formula 1. As used herein, the cross-linked structures may be referred to as a network of metal structures.

According to some example embodiments, the second light may have a longer wavelength than the first light. According to some example embodiments, the second light may have a wavelength of about 300 nm to about 450 nm. The second light may be selected from, for example, an i-line mercury-lamp (365 nm), a h-line mercury-lamp (405 nm), and a g-line mercury-lamp (436 nm). In some example embodiments, a dose (e.g., energy density) of the second light may be in a range of about 10 mJ/cm² to about 20,000 mJ/cm².

In some example embodiments, the organometallic compound may have an absorbance to the first light, but the organometallic compound may have no sensitivity or relatively low sensitivity to the second light. In some example embodiments, an absorbance of the organometallic compound to light (e.g., the first light) having a wavelength of about 10 nm to about 300 nm may be less than an absorbance of the organometallic compound to light (e.g., the second light) having a wavelength of about 300 nm to about 450 nm. For example, the organometallic compound may not absorb the second light or have a relatively low absorbance of the second light. When the organometallic compound is exposed alone to the second light, a dissociation reaction of the at least one organic ligand may not occur. In some example embodiments, the at least one organic ligand of the organometallic compound may be oxidized or reduced due to the photosensitive additive being excited by absorbing the second light, and the at least one organic ligand may be dissociated from the metal core or linked to another adjacent organic ligand. In the presence of the photosensitive additive, the organometallic compound may be dissociated or cross-linked when exposed to the second light having lower energy than the first light. For example, a photoresist composition according to a comparative example, which does not include a photosensitive additive (e.g., does not include any photosensitive additive), may not cause an additional dissociation or cross-linking reaction of an organometallic compound even when the photoresist composition is exposed to the second light.

In some example embodiments, the photosensitive additive may be excited when exposed (e.g., based on being exposed) to the second light, and the excited photosensitive additive may induce some organic ligands of X¹¹, X¹², R¹¹, and R¹² of the Formula 1 to dissociate from the metal core M or induce a cross-linking reaction between X¹¹, X¹², R¹¹, and R¹² of different organometallic compounds.

According to some example embodiments, the photosensitive additive may be activated by absorbing the second light. In some example embodiments, the photosensitive additive may include at least one of a benzophenone-based compound, a thioxanthone-based compound, an anthraquinone-based compound, a coumarin-based compound, a phenothiazine-based compound, a thiazoline-based compound, a rhodanine-based compound, an eosin-based compound, an erythrosine-based compound, an acridine-based compound, a cyanine-based compound, a nitrobenzyl alcohol derivative, or a quinolinone derivative.

In some example embodiments, the benzophenone-based compound may include at least one of benzophenone, 4-phenyl benzophenone, 4-methoxy benzophenone, 4,4′-dimethoxy benzophenone, 4,4′-dimethyl benzophenone, 4,4′-dichlorobenzophenone, 4,4′-bis(dimethylamino)-benzophenone, 4,4′-bis(diethylamino)benzophenone, 4,4′-bis(methylethylamino)benzophenone, 4,4′-bis(p-isopropylphenoxy)benzophenone, 4-methyl benzophenone, 2,4,6-trimethylbenzophenone, 4-(4-methylthiophenyl)-benzophenone, 3,3′-dimethyl-4-methoxy benzophenone, methyl-2-benzoylbenzoate, 4-(2-hydroxyethylthio)-benzophenone, 4-(4-tolylthio)-benzophenone, 1-[4-(4-benzoyl-phenylsulfanyl)-phenyl]-2-methyl-2-(toluene-4-sulfonyl)-propane-1-one, 4-benzoyl-N,N,N-trimethylbenzenemethanaminium chloride, 2-hydroxy-3-(4-benzoylphenoxy)-N,N,N-trimethyl-1-propanaminium chloride monohydrate, 4-(13-acryloyl-1,4,7,10,13-pentaoxatridecyl)-benzophenone, or 4-benzoyl-N,N-dimethyl-N-[2-(1-oxo-2-prophenyl)oxy]ethyl-benzenemethanaminium chloride.

In some example embodiments, the thioxanthone-based compound may include at least one of thioxanthone, 2-isopropylthioxanthone, 2-methylthioxanthone, 2-chlorothioxanthone, 1-chloro-4-propoxythioxanthone, 2-dodecylthioxanthone, 2,4-diethylthioxanthone, 2,4-dimethylthioxanthone, 1-methoxy-carbonylthioxanthone, 2-ethoxycarbonylthioxanthone, 3-(2-methoxyethoxycarbonyl)-thioxanthone, 4-butoxycarbonylthioxanthone, 3-butoxycarbonyl-7-methylthioxanthone, 1-cyano-3-chlorothioxanthone, 1-ethoxycarbonyl-3-chlorothioxanthone, 1-ethoxycarbonyl-3-ethoxythioxanthone, 1-ethoxycarbonyl-3-aminothioxanthone, 1-ethoxycarbonyl-3-phenylsulfuryl thioxanthone, 3,4-di-[2-(2-methoxyethoxy)ethoxycarbonyl]-thioxanthone, 1,3-dimethyl-2-hydroxy-9H-thioxanthene-9-one 2-ethylhexylether, 1-ethoxycarbonyl-3-(1-methyl-1-morpholinoethyl)-thioxanthone, 2-methyl-6-dimethoxymethyl-thioxanthone, 2-methyl-6-(1,1-dimethoxybenzyl)-thioxanthone, 2-morpholinomethylthioxanthone, 2-methyl-6-morpholinomethylthioxanthone, N-allylthioxanthone-3,4-dicarboximide, N-octylthioxanthone-3,4-dicarboximide, N-(1,1,3,3-tetramethylbutyl)-thioxanthone-3,4-dicarboximide, 1-phenoxythioxanthone, 6-ethoxycarbonyl-2-methoxythioxanthone, 6-ethoxycarbonyl-2-methylthioxanthone, thioxanthone-2-carboxylic acid polyethyleneglycol ester, or 2-hydroxy-3-(3,4-dimethyl-9-oxo-9H-thioxanthone-2-yloxy)-N,N,N-trimethyl-1-propanaminium chloride.

In some example embodiments, the coumarin-based compound may include at least one of coumarin 1, coumarin 2, coumarin 6, coumarin 7, coumarin 30, coumarin 102, coumarin 106, coumarin 138, coumarin 152, coumarin 153, coumarin 307, coumarin 314, coumarin 314T, coumarin 334, coumarin 337, coumarin 500, 3-benzoyl coumarin, 3-benzoyl-7-methoxycoumarin, 3-benzoyl-5,7-dimethoxycoumarin, 3-benzoyl-5,7-dipropoxycoumarin, 3-benzoyl-6,8-dichlorocoumarin, 3-benzoyl-6-chloro-coumarin, 3,3′-carbonyl-bis[5,7-di(propoxy)coumarin], 3,3′-carbonyl-bis(7-methoxycoumarin), 3,3′-carbonyl-bis(7-diethylamino-coumarin), 3-isobutyloyl coumarin, 3-benzoyl-5,7-dimethoxy-coumarin, 3-benzoyl-5,7-diethoxy-coumarin, 3-benzoyl-5,7-dibutoxycoumarin, 3-benzoyl-5,7-di(methoxyethoxy)-coumarin, 3-benzoyl-5,7-di(allyloxy)coumarin, 3-benzoyl-7-dimethylaminocoumarin, 3-benzoyl-7-diethylaminocoumarin, 3-isobutyloyl-7-di-methylaminocoumarin, 5,7-dimethoxy-3-(1-naphthoyl)-coumarin, 5,7-diethoxy-3-(1-naphthoyl)-coumarin, 3-benzoylbenzo[f]coumarin, 7-diethylamino-3-thienoyl coumarin, 3-(4-cyanobenzoyl)-5,7-dimethoxycoumarin, 3-(4-cyanobenzoyl)-5,7-dipropoxycoumarin, 7-dimethylamino-3-phenylcoumarin, or 7-diethylamino-3-phenylcoumarin.

In some example embodiments, the thiazoline-based compound may include at least one of 3-methyl-2-benzoylmethylene-β-naphthothiazoline, 3-methyl-2-benzoylmethylene-benzothiazoline, or 3-ethyl-2-propionylmethylene-β-naphthothiazoline. In some example embodiments, the thiozine-based compound may include at least one of phenothiazine or methylphenothiazine. In some example embodiments, the rhodanine-based compound may include at least one of 4-dimethylaminobenzalrhodanine, 4-diethylaminobenzalrhodanine, or 3-ethyl-5-(3-octyl-2-benzothiazolinylidene)-rhodanine. In some example embodiments, the eosin-based compound may include eosin Y. In some example embodiments, the rhodanine-based compound may include at least one of rhodanine 6G, rhodanineB, or rhodanine WT. In some example embodiments, the anthraquinone-based compound may include at least one of anthraquinone, 2-ethylanthraquinone, or 9,10-anthraquinone.

In addition, the photosensitive additive may include at least one of 9-phenylacridin, 1,7-bis(9-acridinyl)heptane, 1,5-bis(9-acridinyl)pentane, cyanine, merocyanine, n-phenylglycine, naphthoquinone, phenanthraquinone, benzoin, benzoinmethylether, benzoinisopropylether, benzoin-n-butylether, benzoin-phenylether, methylbenzoin, ethylbenzoin, dibenzyl, benzyldiphenyl disulfide, benzyldimethylketal, 1,1-dichloroacetophenone, p-t-butyldichloroacetophenone, 2,2-diethoxyacetophenone, 2,2-dimethoxy-2-phenylacetophenone, 2,2-dichloro-4-phenoxyacetophenone, or 4-dimethylaminoacetophenone.

In some example embodiments, the photosensitive additive may include at least one selected from compounds represented by the following Formulas.

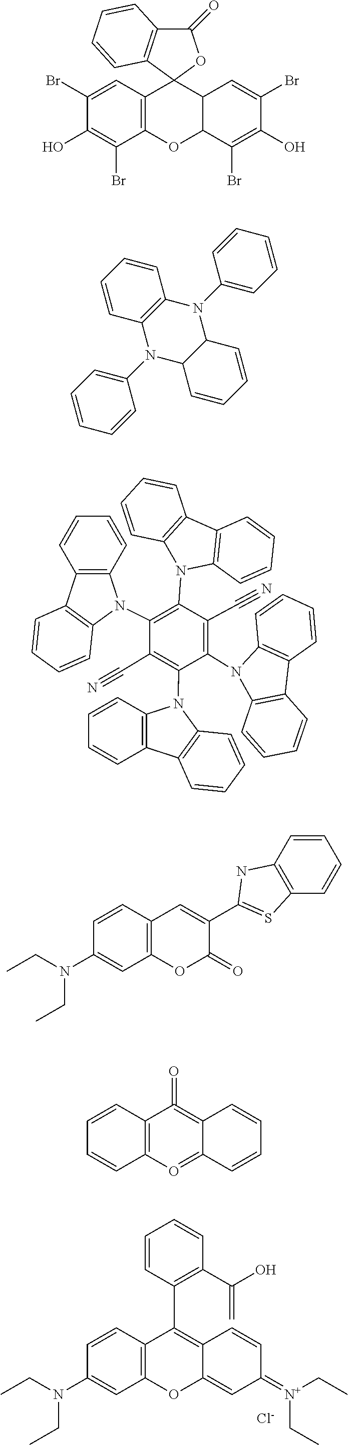

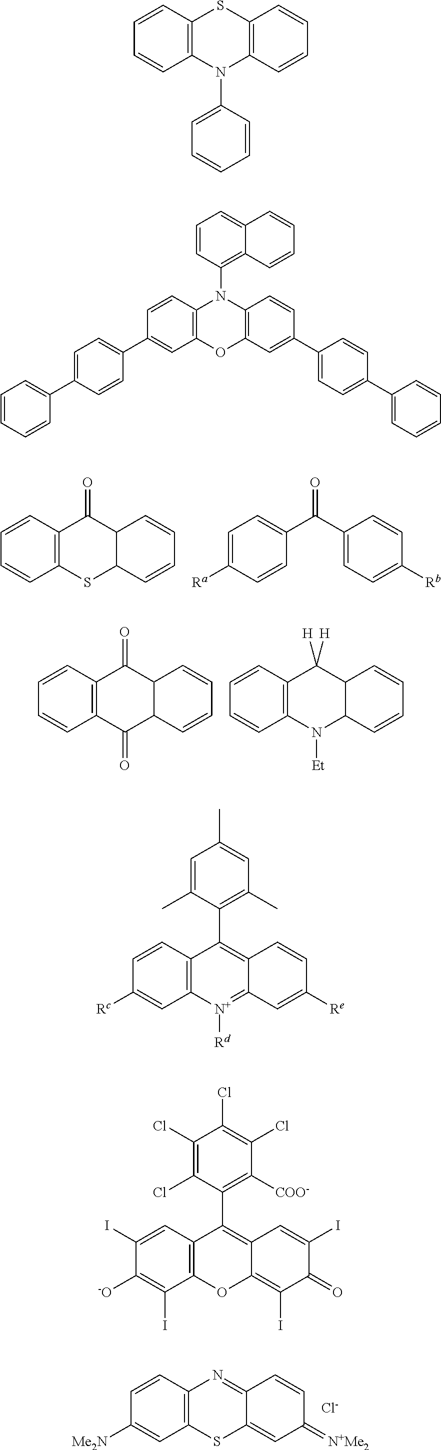

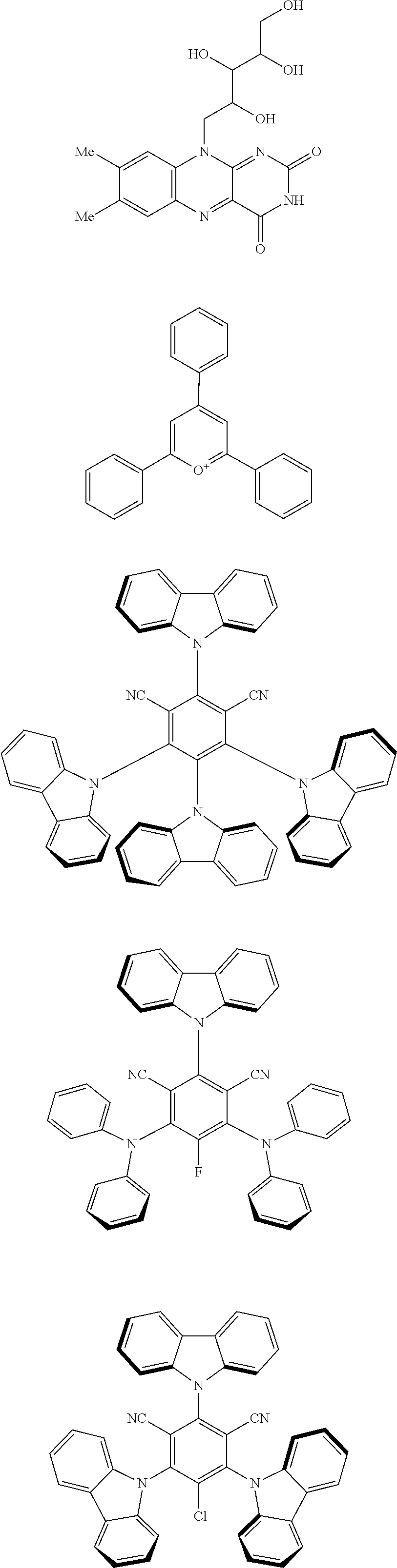

In some example embodiments, a molar ratio of the photosensitive additive to the organometallic compound may be in a range of about 0.01 to about 0.2. When a content of the photosensitive additive is higher than the above-described range (e.g., greater than about 0.2), a cross-linking reaction may be promoted in an undesired region, and thus, contrast characteristics may be degraded. Conversely, when the content of the photosensitive additive is lower than the above-described range (e.g., less than about 0.01), an oxidation-reduction reaction of the organometallic compound may not be sufficiently induced, and thus, a pattern may not be formed.

According to some example embodiments, the second light may be used supplementally in addition to the first light. To form a pattern with a desired fine pitch using only the first light (e.g., EUV laser) without degrading a critical dimension (CD) distribution, a large dose (e.g., high energy density) of light may be required, and thus, the use of high energy may be needed. However, when the second light (e.g., an i-line mercury lamp) is supplementarily and additionally used, a fine pattern may be formed by further using relatively low energy, which may result in reducing power consumption of a method of forming the pattern, and in some example embodiments a method of manufacturing an integrated circuit device that includes the method of forming the pattern.

For example, the organometallic compound exposed to a first dose of the first light may not form enough radicals to form a desired pattern. In some example embodiments, an organometallic compound having a high reactivity may be used to form a desired level of fine pattern at the first dose. However, in some example embodiments, storage stability of the photoresist composition may be reduced. Because the photoresist composition according to some example embodiments includes the photosensitive additive, the photosensitive additive may be excited by the second light that is additionally used, and the organometallic compound may react with the excited photosensitive additive to form additional reactive groups or radicals. In some example embodiments, a cross-linking reaction between organic ligands of different organometallic compounds may be induced. Accordingly, the photoresist composition according to some example embodiments may promote a cross-linking reaction in an exposed area due to the second light using relatively low energy, and thus, a dose (e.g., energy density) of the first light (e.g., EUV) may be lowered and good-quality pattern formation properties may be achieved. This improves the quality of the pattern formed by the method, and thus improves the quality of the structure of an integrated circuit device that includes such a pattern. Such properties may be achieved with reduced power consumption due to the use of reduced doses (e.g., energy density) of the first light without compromising the quality of pattern formation properties in the method of forming the pattern. In addition, the roughness of an edge portion of a pattern may improve, and a pattern with excellent contrast may be formed, thereby improving the quality of the pattern formed by the method, and thus improving the quality of the structure of an integrated circuit device that includes such a pattern. As described herein, an improved quality of a pattern formation property and/or any properties (e.g., dimensions) of a pattern may include improved accuracy and/or precision of conformance of such pattern formation property and/or properties (e.g., dimensions) of the pattern that is formed in a method according to some example embodiments in relation to design dimensions of a design for such a pattern, such that the formed pattern conforms more closely to the design thereof. An improved quality of the structure of an integrated circuit device that includes such a pattern as a result of performing the method that uses the photoresist composition to form at least one pattern according to some example embodiments may result in improved reliability of the integrated circuit device based on reducing the likelihood of process defects in the integrated circuit device structure due to the improved quality of the pattern formed based on utilizing the photoresist composition in the method according to some example embodiments.

The first light and the second light according to some example embodiments may be used sequentially or in different orders. In some example embodiments, after the organometallic compound is directly reacted by firstly using the first light, the organometallic compound may be further reacted by exciting the photosensitive additive by using the second light. In some example embodiments, after the organometallic compound is reacted by exciting the photosensitive additive by using the second light, the organometallic compound may be further directly reacted by using the first light. In some example embodiments, after the second light and the first light are sequentially used, the second light may be additionally used again.

The organometallic compound included in the photoresist composition according to some example embodiments may be obtained by purchasing a commercially available product or by synthesizing a known precursor using methods known to one skilled in the art.

In some example embodiments, the photoresist composition may further include a photoinitiator. The photoinitiator may generate acid or radicals by absorbing the first light. After (subsequently to) a photoresist film obtained from the photoresist composition is exposed to the first light, the photoinitiator may generate acid or radicals by absorbing the first light in an exposed area of the photoresist film. The acid or radicals generated by the photoinitiator may react with the organic ligand of the organometallic compound and induce a dissociation reaction of the organic ligand. Thus, when the photoinitiator is included in the photoresist composition according to some example embodiments, the organic ligand may be deprotected from the organometallic compound due to the acid or radicals generated by the photoinitiator, and a cross-linking reaction between adjacent molecules may occur during an exposure or bake process.

When the photoinitiator is included in the photoresist composition according to some example embodiments, the photoinitiator may supplement a relatively low reactivity of the organometallic compound when the photoresist film obtained from the photoresist composition is exposed, and a sensitivity of the photoresist film to the first light in the exposed area may be adjusted according to a content of the photoinitiator. In particular, the photoinitiator may promote a ligand dissociation reaction of the organometallic compound by using the acid or radicals in the exposed area of the photoresist film and induce a limited photoreaction only in the exposed area of the photoresist film.

The photoinitiator may include a photoacid generator (PAG) configured to generate acid due to the first light, a photoradical generator (PRG) configured to generate radicals due to the first light, or a combination of the PAG and the PRG.

The PAG may generate an acid when exposed to any one selected from a KrF excimer laser (248 nm), an ArF excimer laser (193 nm), a F₂ excimer laser (157 nm), and an EUV laser (13.5 nm). In some example embodiments, the PAG may include triarylsulfonium salts, diaryliodonium salts, sulfonates, or any mixture thereof. For example, the PAG may include triphenylsulfonium triflate, triphenylsulfonium antimonate, diphenyliodonium triflate, diphenyliodonium antimonate, methoxydiphenyliodonium triflate, di-t-butyldiphenyliodonium triflate, 2,6-dinitrobenzyl sulfonates, pyrogallol tris(alkylsulfonates), N-hydroxysuccinimide triflate, norbornene-dicarboximide-triflate, triphenylsulfonium nonaflate, diphenyliodonium nonaflate, methoxydiphenyliodonium nonaflate, di-t-butyldiphenyliodonium nonaflate, N-hydroxysuccinimide nonaflate, norbornene-dicarboximide-nonaflate, triphenylsulfonium perfluorobutanesulfonate, triphenylsulfonium perfluorooctanesulfonate (PFOS), diphenyliodonium PFOS, methoxydiphenyliodonium PFOS, di-t-butyldiphenyliodonium triflate, N-hydroxysuccinimide PFOS, norbornene-dicarboximide PFOS, or any mixture thereof, without being limited thereto.

When the PRG is exposed (e.g., based on the PRG being exposed) to any one selected from a KrF excimer laser (248 nm), an ArF excimer laser (193 nm), a F₂ excimer laser (157 nm), and an EUV laser (13.5 nm), the PRG may generate radicals by absorbing the selected light, and thus, the polymerization of the organometallic compound included in the photoresist composition according to some example embodiments may be initiated. In some example embodiments, the PRG may include an acylphosphine oxide-based compound or an oxime ester-based compound.

The acylphosphine oxide-based compound may include, for example, at least one of 2,4,6-trimethylbenzoyl-diphenylphosphine oxide, bis(2,4,6-trimethylbenzoyl)-phenylphosphine oxide, or bis(2,6-dimethoxybenzoyl)-(2,4,4-trimethylpentyl)phosphine oxide.

The oxime ester-based compound may include, for example, at least one of 1-phenylpropane-1,2-dione-2-(O-ethoxycarbonyl)oxime, 1-phenylbutane-1,2-dione-2-(O-methoxycarbonyl)oxime, 1,3-diphenylpropane-1,2,3-trione-2-(O-ethoxycarbonyl)oxime, 1-[4-(phenylthio)phenyl]octane-1,2-dione-2-(O-benzoyl)oxime, 1-[4-[4-(carboxyphenyl)thio]phenyl]propane-1,2-dione-2-(O-acetyl)oxime, 1-[9-ethyl-6-(2-methylbenzoyl)-9H-carbazol-3-yl]ethanone-1-(O-acetyl)oxime, or 1-[9-ethyl-6-[2-methyl-4-[1-(2,2-dimethyl-1,3-dioxolane-4-yl)methyloxy]benzoyl]-9H-carbazol-3-yl]ethanone-1-(0-acetyl)oxime.

In some example embodiments, commercially available products (manufactured by BASF), such as IRGACURE 651, IRGACURE 184, IRGACURE 1173, IRGACURE 2959, IRGACURE 127, IRGACURE 907, IRGACURE 369, IRGACURE 379, IRGACURE TPO, IRGACURE 819, IRGACURE OXE01, IRGACURE OXE02, IRGACURE MBF, and/or IRGACURE 754, may be used as the PRG.

The photoresist composition according to the inventive concepts may not include the photoinitiator (e.g., may not include any photoinitiator). The photoinitiator may include only a single material selected from the PAG and the PRG or at least two kinds of materials selected from the PAG and the PRG. When the photoinitiator is included in the photoresist composition according to some example embodiments, the photoinitiator may be contained in the photoresist composition at a content of about 0.02% to about 10% by weight, based on a total weight of the organometallic compound, without being limited thereto.

The solvent included in the photoresist composition may include an organic solvent. The solvent may include at least one of ether, alcohol, glycol ether, an aromatic hydrocarbon compound, ketone, or ester, without being limited thereto. For example, the organic solvent may include ethyleneglycolmonomethylether, ethyleneglycolmonoethylether, methylcellosolveacetate, ethylcellosolveacetate, diethyleneglycolmethylether, diethyleneglycolethylether, propyleneglycol, propyleneglycolmethylether (PGME), propyleneglycolmethyletheracetate (PGMEA), propyleneglycolethylether, propyleneglycolethyletheracetate, propyleneglycolpropyletheracetate, propyleneglycolbutylether, propyleneglycolbutyletheracetate, ethanol, propanol, isopropylalcohol, isobutylalcohol, 4-methyl-2-pentanol (methyl isobutyl carbion: MIBC), hexanol, 1-methoxy-2-propanol, 1-ethoxy-2-propanol, ethyleneglycol, propyleneglycol, heptanone, propylenecarbonate, butylene carbonate, toluene, xylene, methylethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, gamma-butyrolactone, methyl 2-hydroxyisobutyrate, methoxybenzene, n-butyl acetate, 1-methoxy-2-propyl acetate, methoxyethoxy propionate, ethoxyethoxy propionate, or any combination thereof.

In the photoresist composition according to some example embodiments, the solvent may be contained in the photoresist composition at a content of the remaining percentage excluding the contents of main components including the organometallic compound and the photosensitive additive. In some example embodiments, the solvent may be contained in the photoresist composition at a content of about 70% to about 99.8% by weight, based on a total weight of the photoresist composition, without being limited thereto.

In some example embodiments, when the photoresist composition according to some example embodiments includes the PAG as the photoinitiator, the photoresist composition may further include a basic quencher. The acid generated from the PAG or acid generated from another photo-decomposable compound in the photoresist composition according to some example embodiments may diffuse into a non-exposed area of the photoresist film, and the basic quencher may include a compound capable of trapping the acid in the non-exposed area. Because the basic quencher is included in the photoresist composition according to some example embodiments, a diffusion rate of the acid may be inhibited in the photoresist film obtained from the photoresist composition.

In some example embodiments, the basic quencher may include primary aliphatic amine, secondary aliphatic amine, tertiary aliphatic amine, aromatic amine, heterocyclic ring-containing amine, a nitrogen-containing compound having a carboxyl group, a nitrogen-containing compound having a sulfonyl group, a nitrogen-containing compound having a hydroxyl group, a nitrogen-containing compound having a hydroxyphenyl group, an alcoholic nitrogen-containing compound, amides, imides, carbamates, or ammonium salts. For example, the basic quencher may include triethanol amine, triethyl amine, tributyl amine, tripropyl amine, hexamethyl disilazan, aniline, N-methylaniline, N-ethylaniline, N-propylaniline, N,N-dimethylaniline, N,N-bis(hydroxyethyl)aniline, 2-methylaniline, 3-methylaniline, 4-methylaniline, ethylaniline, propylaniline, dimethylaniline, 2,6-diisopropylaniline, trimethylaniline, 2-nitroaniline, 3-nitroaniline, 4-nitroaniline, 2,4-dinitroaniline, 2,6-dinitroaniline, 3,5-dinitroaniline, N,N-dimethyltoluidine, or any combination thereof, but is not limited thereto.

In some example embodiments, the basic quencher may include a photobase generator. The photobase generator may absorb active energy rays due to light irradiation, and thus, a chemical structure of the photobase generator may decompose to generate a base. Accordingly, when a partial area of the photoresist film formed from the photoresist composition including the basic quencher including the photobase generator is exposed (e.g., based on such exposure), the photobase generator may trap an acid in the exposed area of the photoresist film, and thus, sensitivity may be adjusted in the exposed area, and the diffusion of the acid from the exposed area into the non-exposed area may be reduced, minimized, or prevented. Therefore, a network of metal structures, which includes a metal oxide including the metal core, may be selectively formed only in the exposed area of the photoresist film. Adverse effects due to undesired diffusion of the acid (e.g., the deterioration of a CD distribution at an edge of a photoresist pattern obtained after a developing process) may be reduced, minimized, or prevented, thereby improving the quality of the structure of the network of metal structures and thus reducing the likelihood of process defects in the network of metal structure, thereby improving the structure and reliability of a device (e.g., an integrated circuit device) including such a network of metal structures.

The photobase generator may be used without any particular limitation when the photobase generator includes any material capable of generating a base due to light irradiation. In some example embodiments, the photobase generator may include a nonionic photobase generator. In some example embodiments, the photobase generator may include an ionic photobase generator.

In some example embodiments, the photobase generator may include a carboxylate or sulfonate salt of a photo-labile cation. For example, the photo-labile cation included in the photobase generator may include a sulfonium cation. The sulfonium cation may include at least one of a substituted or unsubstituted C1 to C12 alkyl group, a substituted or unsubstituted C3 to C12 cycloalkyl group, a C6 to C30 aryl group, or a C2 to C30 heteroaryl group. Each of the alkyl group, the cycloalkyl group, the aryl group, and the heteroaryl group may include at least one heteroatom selected from an O atom, an S atom, and a N atom. For example, the sulfonium cation may include a phenyl group, a cyclopentyl group, a cyclohexyl group, an adamantyl group, a methyl group, an ethyl group, a propyl group, a butyl group, a t-butyl group, or an isopropyl group, without being limited thereto.

The photo-labile cation included in the photobase generator may form a complex with an anion of C1 to C20 carboxylic acid. The carboxylic acid may be, for example, formic acid, acetic acid, propionic acid, tartaric acid, succinic acid, cyclohexylcarboxylic acid, benzoic acid, or salicylic acid, without being limited thereto.

In some example embodiments, triphenylsulfonium heptafluorobutyric acid or triphenyl sulfonium hexafluoroantimonate (TPS-SbF₆) may be used as the photobase generator, without being limited thereto.

In the photoresist composition according to the inventive concepts, the basic quencher may be used alone or in a mixture of at least two kinds thereof. The basic quencher may be contained at a molar ratio of about 0.01 to about 0.5 based on a total content of the organometallic compound, without being limited thereto.

In some example embodiments, when the photoresist composition according to some example embodiments includes the PRG as the photoinitiator, the photoresist composition may further include a radical quencher capable of trapping radicals.

In some example embodiments, the radical quencher may include a quinone-type free radical or a nitroxide (IUPAC name: aminoxyl) free radical.

The quinone-type free radical may include p-benzoquinone, hydroquinone(1,4-dihydroxybenzene), hydroquinone monomethyl ether(4-methoxyphenol), hydroquinone monomethyl ether, hydroquinone monophenyl ether, mono-t-butyl hydroquinone (MTBHQ), di-t-butyl hydroquinone, di-t-amyl hydroquinone, toluhydroquinone, p-benzoquinone dioxime, 2,6-dichloro-1,4-benzoquinone, 2,3,5,6-tetramethyl-1,4-benzoquinone, 2,5-dichloro-3,6-dihydroxy-p-benzoquinone, methyl-p-benzoquinone, 6-anilinoquinoline-5,8-quinone, pyrroloquinoline quinone, 2-allyl-6-methoxybenzo-1,4-quinone, or any combination thereof, without being limited thereto.

The nitroxide free radical may include di-tert-butyl nitroxide (DTBN), 2,2,6,6-tetramethyl-1-peperidine 1-oxyl (TEMPO), 4-oxo-2, 2, 6, 6-tetramethyl-1-peperidine 1-oxyl (oxo TEMPO), 1,1,3,3-tetraethylisoindoline-N-oxyl, N-tert-butyl-N-[1-(diethoxyphosphoryl)-2,2-dimethylpropyl]aminoxyl (SG1), N-tert-butyl-N-(2-methyl-1-phenylpropyl) aminoxyl (TIPNO), or any combination thereof, without being limited thereto.

When a photolithography process is performed (e.g., based on a photolithography process being performed) by using a photoresist composition according to the inventive concepts, the radicals generated by the PRG may be quenched by the radical quencher in the exposed area of the photoresist film obtained from the photoresist composition. Thus, sensitivity may be adjusted in the exposed area, and the radicals flowing from the exposed area to the non-exposed area may be quenched by the radical quencher. Accordingly, a network including a metal oxide including the metal core may be selectively formed only in the exposed area. Adverse effects due to undesired diffusion of the radicals (e.g., the deterioration of a CD distribution at the edge of the photoresist pattern obtained after a developing process) may be reduced, minimized, or prevented, thereby improving the quality of the structure of the network of metal structures and thus reducing the likelihood of process defects in the network of metal structure, thereby improving the structure and reliability of a device (e.g., an integrated circuit device) including such a network of metal structures.

In the photoresist composition according to the inventive concepts, the radical quencher may be used alone or in a mixture of at least two kinds thereof. The radical quencher may be contained at a molar ratio of about 0.01 to about 0.5 based on a total content of the organometallic compound, without being limited thereto.

In some example embodiments, the photoresist composition according to some example embodiments may further include at least one selected from a leveling agent, a surfactant, a dispersant, a desiccant, and a coupling agent.

The leveling agent may be a known, commercially available leveling agent, which may improve coating flatness when the photoresist composition is coated on a substrate.

The surfactant may improve the coating uniformity and wettability of the photoresist composition. In some example embodiments, the surfactant may include sulfuric acid ester salts, sulfonates, phosphate ester, soap, amine salts, quaternary ammonium salts, polyethylene glycol, alkylphenol ethylene oxide adducts, polyhydric alcohol, a nitrogen-containing vinyl polymer, or any combination thereof, without being limited thereto. For example, the surfactant may include alkylbenzene sulfonates, alkylpyridinium salts, polyethylene glycol, or quaternary ammonium salts. When the photoresist composition includes the surfactant, the surfactant may be contained at a content of about 0.001% to about 3% by weight, based on the total weight of the photoresist composition.

The dispersant may uniformly disperse respective components in the photoresist composition. In some example embodiments, the dispersant may include an epoxy resin, polyvinyl alcohol, polyvinyl butyral, polyvinylpyrrolidone, glucose, sodium dodecyl sulfate, sodium citrate, oleic acid, linoleic acid, or any combination thereof, without being limited thereto. When the photoresist composition includes the dispersant, the dispersant may be contained at a content of about 0.001% to about 5% by weight, based on the total weight of the photoresist composition.

The desiccant may reduce, minimize, or prevent adverse effects due to moisture in the photoresist composition. In some example embodiments, the desiccant may include polyoxyethylene nonylphenolether, polyethylene glycol, polypropylene glycol, polyacrylamide, or any combination thereof, without being limited thereto. When the photoresist composition includes the desiccant, the desiccant may be contained at a content of about 0.001% to about 10% by weight, based on the total weight of the photoresist composition.

The coupling agent may increase adhesion of the photoresist composition with a lower film when the lower film is coated (e.g., based on the lower film being coated) with the photoresist composition. In some example embodiments, the coupling agent may include a silane coupling agent. The silane coupling agent may include vinyl trimethoxysilane, vinyl triethoxysilane, vinyl trichlorosilane, vinyl tris(β-methoxyethoxy)silane, 3-methacryl oxypropyl trimethoxysilane, 3-acryl oxypropyl trimethoxysilane, p-styryl trimethoxysilane, 3-methacryl oxypropyl methyldimethoxysilane, 3-methacryl oxypropyl methyldiethoxysilane, or trimethoxy[3-(phenylamino)propyl]silane, without being limited thereto. When the photoresist composition includes the coupling agent, the coupling agent may be contained at a content of about 0.001% to about 5% by weight, based on the total weight of the photoresist composition.

The photoresist composition according to some example embodiments may include the organometallic compound including a metal-ligand bond between the metal core and the organic ligand and the photosensitive additive. In some example embodiments, the organometallic compound may have an absorbance to first light having a wavelength range of about 10 nm to about 300 nm, and the photosensitive additive may have an absorbance to second light having a wavelength range of about 300 nm to about 450 nm. The organometallic compound may absorb the first light to form radicals, and absorb the second light to form supplementary radicals due to the excited photosensitive additive. Accordingly, the dimensional precision of a pattern may improve while reducing a dose of short-wavelength light, and the storage stability of the photoresist composition may improve.

Hereinafter, a method of manufacturing an IC device by using the photoresist composition according to some example embodiments is described.

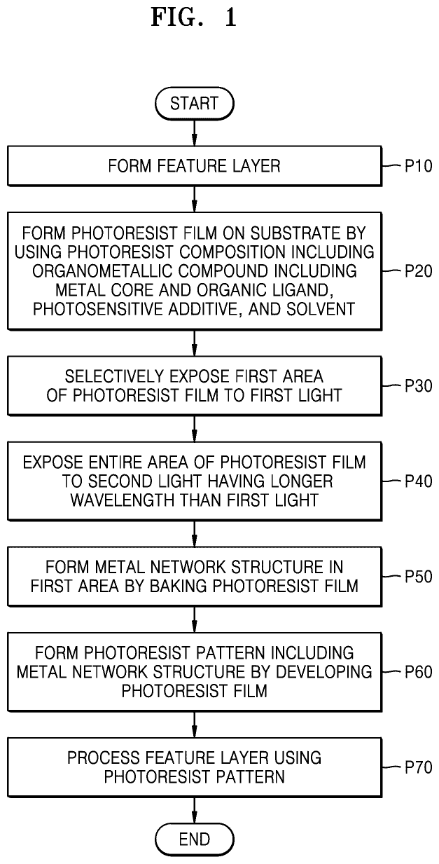

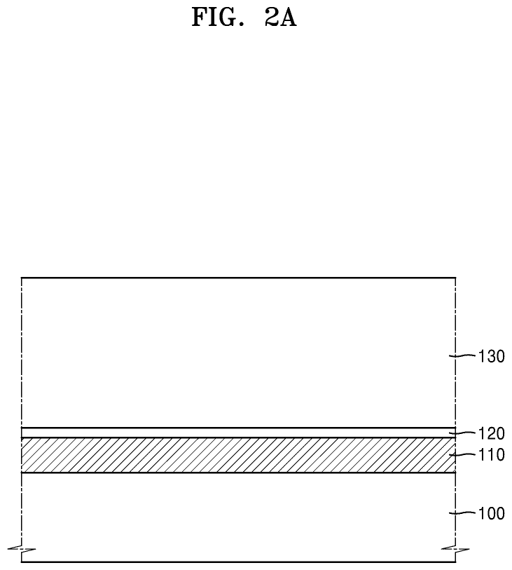

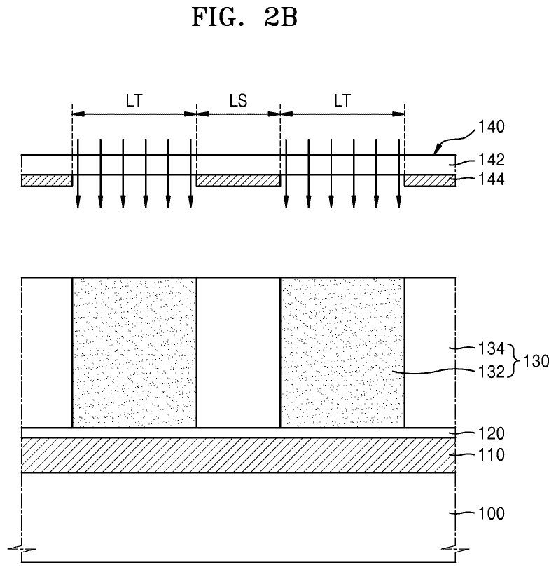

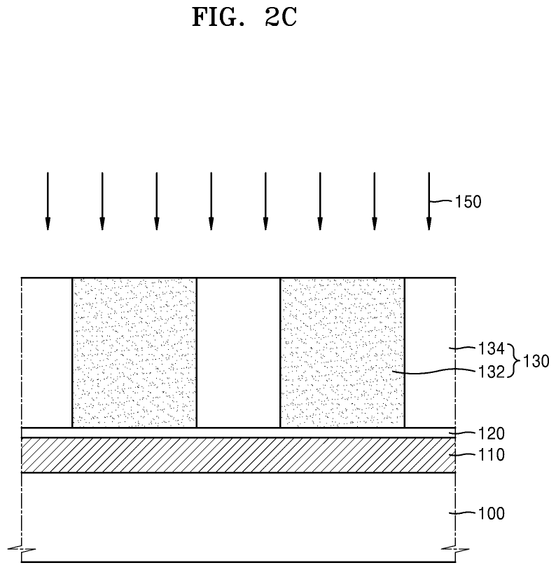

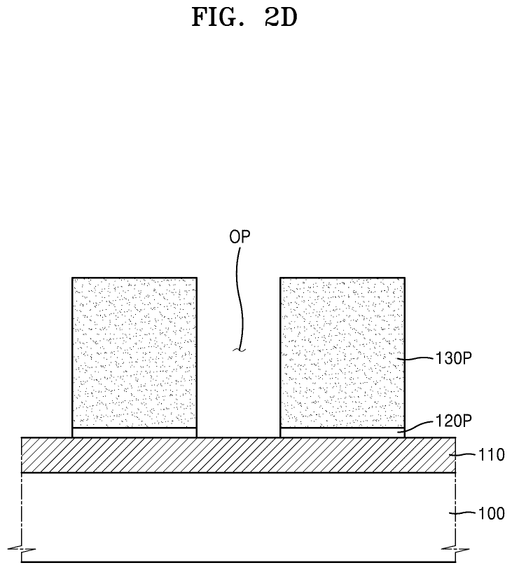

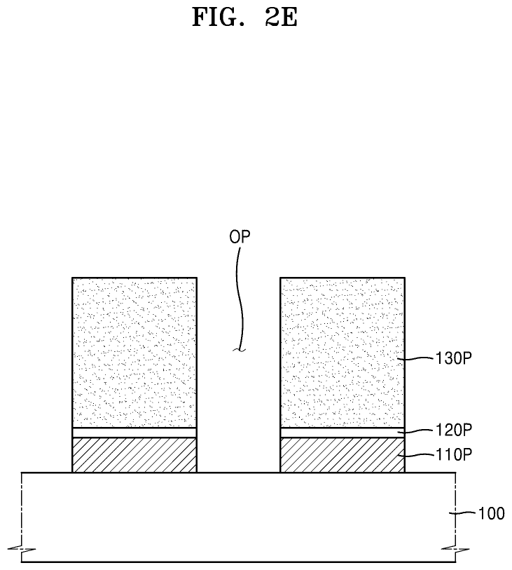

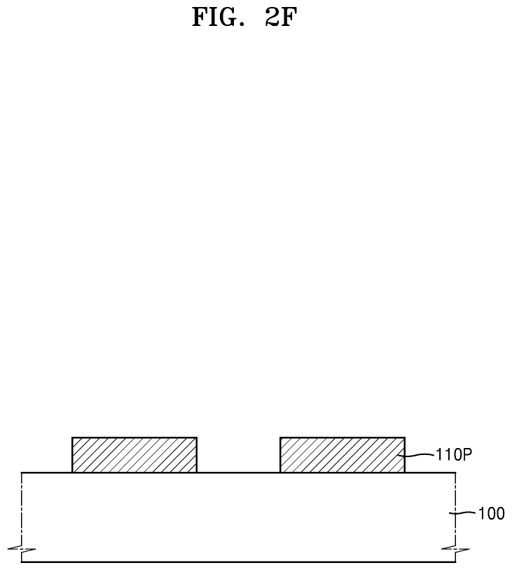

FIG. 1 is a flowchart of a method of manufacturing an integrated circuit (IC) device, according to some example embodiments. FIGS. 2A, 2B, 2C, 2D, 2E, and 2F are cross-sectional views of a process sequence of a method of manufacturing an IC device, according to some example embodiments.

Referring to FIGS. 1 and 2A, in process P10, a feature layer 110 may be formed on the substrate 100. Thereafter, in process P20, a photoresist film 130 may be formed on the feature layer 110 using a photoresist composition according to some example embodiments. Details of the photoresist composition are the same as those described above.

The substrate 100 may include a semiconductor substrate. The feature layer 110 may include an insulating film, a conductive film, or a semiconductor film. For example, the feature layer 110 may include a metal, an alloy, a metal carbide, a metal nitride, a metal oxynitride, a metal oxycarbide, a semiconductor, polysilicon, oxide, nitride, oxynitride, or any combination thereof, without being limited thereto.

In some example embodiments, as shown in FIG. 2A, before the photoresist film 130 is formed on the feature layer 110, a lower film 120 may be formed on the feature layer 110. In some example embodiments, the photoresist film 130 may be formed on the lower film 120. The lower film 120 may prevent the photoresist film 130 from being adversely affected by the feature layer 110 located thereunder or may reduce or minimize such adverse effects. In some example embodiments, the lower film 120 may include an organic or inorganic anti-reflective coating (ARC) material for a KrF excimer laser, an ArF excimer laser, an EUV laser, or any other light source. In some example embodiments, the lower film 120 may include a bottom anti-reflective coating (BARC) film or a developable bottom anti-reflective coating (DBARC) film. In some example embodiments, the lower film 120 may include an organic component having a light-absorbing structure. The light-absorbing structure may include, for example, at least one benzene ring or a hydrocarbon compound in which benzene rings are fused. The lower film 120 may be formed to a thickness of about 1 nm to about 100 nm, without being limited thereto. In some example embodiments, the lower film 120 may be omitted.

To form the photoresist film 130, a photoresist composition according to some example embodiments may be coated on the lower film 120 and annealed. The coating process may be performed using, for example, at least one of a spin coating process, a spray coating process, or a deep coating process. The process of annealing the photoresist composition may be performed at a temperature of about 80° C. to about 150° C. for about 20 seconds to about 100 seconds, without being limited thereto. A thickness of the photoresist film 130 may be several times to several hundred times a thickness of the lower film 120. The photoresist film 130 may be formed to a thickness of about 10 nm to about 1 m, without being limited thereto.

Referring to FIGS. 1 and 2B, in process P30, a first area 132, which is a portion of the photoresist film 130, may be selectively exposed to first light.

In some example embodiments, to expose the first area 132 of the photoresist film 130, a photomask 140 having a plurality of light-shielding areas LS and a plurality of light-transmitting areas LT may be arranged at a particular (or, alternatively, predetermined) position on the photoresist film 130, and the first area 132 of the photoresist film 130 may be exposed through the plurality of light-transmitting areas LT of the photomask 140.

In some example embodiments, the photomask 140 may include a transparent substrate 142 and a plurality of light-shielding patterns 144 formed in the plurality of light-shielding areas LS on the transparent substrate 142. The transparent substrate 142 may include quartz. The plurality of light-shielding patterns 144 may include chromium (Cr). The plurality of light-transmitting areas LT may be defined by the plurality of light-shielding patterns 144. According to the inventive concepts, a reflective photomask (not shown) for EUV exposure may be used instead of the photomask 140 to expose the first area 132 of the photoresist film 130.

In some example embodiments, as described above, the first light may have a relatively short wavelength of about 10 nm to about 300 nm, and a dose (e.g., energy density) of the first light may be about 10 mJ/cm² to about 200 mJ/cm². For example, a KrF excimer laser (248 nm), an ArF excimer laser (193 nm), a F₂ excimer laser (157 nm), or an EUV laser (13.5 nm) may be used as the first light.

An organometallic compound of the first area 132 may form radicals by directly absorbing the first light. In some example embodiments, in the organometallic compound of the first area 132, an organic ligand may be deprotected from a metal core, and thus, the metal core and/or the deprotected organic ligand may form radicals. In some example embodiments, the organic ligand bonded to the metal core may form reactive radicals.

In some example embodiments, an acid or radicals may be generated from a photoinitiator included in the photoresist film 130. The photoinitiator may include a PAG configured to generate an acid by light, a PRG configured to generate radicals by light, or a combination of the PAG and the PRG. Therefore, while the first area of the photoresist film 130 is being exposed in the process P30 of FIG. 1, the photoinitiator included in the photoresist film 130 in the first area 132 may generate an acid and/or radicals by absorbing light.

Referring to FIGS. 1 and 2C, after the photomask 140 exposed in process P40 is removed, the entire area of the photoresist film 130 may be exposed to second light.

In some example embodiments, the second light may have a wavelength of about 300 nm to about 450 nm, and a dose of the second light may be about 0.1 mJ/cm² to about 50 mJ/cm². For example, an i-line mercury-lamp (365 nm), a h-line mercury-lamp (405 nm), or a g-line mercury-lamp (436 nm) may be used as the second light.

In some example embodiments, a photosensitive additive in the photoresist film 130 may be excited by absorbing the second light. The excited photosensitive additive may induce an oxidation-reduction reaction or a radical formation reaction of the organometallic compound. For example, the excited photosensitive additive may reduce the organometallic compound to cause the deprotection of the organic ligand from the metal core. For example, the excited photosensitive additive may cause a cross-linking reaction between organic ligands of two adjacent organometallic compounds. Accordingly, in addition to the process P30 in which the organometallic compound directly absorbs the first light to form radicals, the organometallic compound may be oxidized or reduced by exciting the photosensitive additive using the second light to form additional radicals. By additionally irradiating the second light using relatively low energy, a pattern with excellent contrast may be ultimately embodied while reducing a dose of the first light using relatively high energy.

In some example embodiments, in the process P40, the first area 132 may be selectively exposed with the second light without removing the photomask 140. In some example embodiments, a photosensitive additive of the first area 132 may be excited by the second light to induce an oxidation-reduction reaction and a radical reaction of the organometallic compound or the organic ligand.

In some example embodiments, the process P40 may be performed before the process P30 of selectively exposing the first area 132 with the first light. For example, after the process P40 is performed first to expose the entire area of the photoresist film 130 using the second light, the process P30 may be performed to selectively expose the first area 132 using the first light.

In some example embodiments, the process P40 may be performed both before and after the process P30. For example, after the process P40 is performed to expose the entire area of the photoresist film 130 using the second light (hereinafter, a pre-treatment process), the process P30 may be performed to selectively expose the first area 132 using the first light, and the process P40 may be performed again to expose the entire area of the photoresist film 130 using the second light (hereinafter, a post-treatment process). The pre-treatment process and the post-treatment process may be performed under different conditions. For example, both the pre-treatment process and the post-treatment process may equally use light having a wavelength of about 300 nm to about 450 nm, but different doses of light may be used. In some example embodiments, the pre-treatment process and the post-treatment process may be performed under the same conditions.

In some example embodiments, after the process P40 is performed, a bake process may be further performed. The bake process that is a subsequent process of the process P40 may be performed at a temperature of about 50° C. to about 200° C. for about 10 seconds to about 150 seconds, but the inventive concepts are not limited thereto. In the bake process that is the subsequent process of the process P40, a reaction in which the organic ligand is protected from the metal core of the organometallic compound or a cross-linking reaction between organic ligands may be further induced.

Thereafter, in process P50, a bake process may be performed by applying heat 150 to the photoresist film 130 including the first area 132. The bake process may be performed at a temperature of about 120° C. to about 200° C. for about 40 seconds to about 250 seconds, without being limited thereto.

In the process P50, an additional dissociation reaction of organic ligands in the organometallic compound included in the photoresist film 130 may be induced in the first area 132, and a condensation reaction of a hydroxyl (—OH) functional group generated at a site from which the organic ligand is deprotected may be induced. Furthermore, a condensation reaction of reactive groups or radicals formed in the process P30 and the process P40 may be induced, and a cross-linking reaction between ligands of different organometallic compounds may be induced to form a dense network of metal structures.

In contrast, a network of metal structures may not be formed in a second area 134 of the photoresist film 130, which is not exposed. Accordingly, a difference in solubility in a developer between the first area 132 and the second area 134 of the photoresist film 130 may be increased.

Referring to FIGS. 1 and 2D, in process P60, the second area 134 of the photoresist film 130 may be removed by developing the photoresist film 130 by using the developer. As a result, a photoresist pattern 130P including the network of the metal structures formed in the first area 132 of the photoresist film 130, which is exposed, may be formed.

The photoresist pattern 130P may include a plurality of openings OP. After the photoresist pattern 130P is formed, portions of the lower film 120, which are exposed through the plurality of openings OP, may be removed to form a lower pattern 120P.

In some example embodiments, the developing of the photoresist film 130 may be performed using a negative-tone development (NTD) process.

In some example embodiments, the photoresist film 130 may be developed by using a developer including an organic solvent. For example, the developer may include ketones such as methylethyl ketone, acetone, cyclohexanone, and/or 2-heptanone; alcohols such as 4-methyl-2-propanol, 1-butanol, isopropanol, 1-propanol, and/or methanol; esters such as propylene glycol monomethyl ether acetate, ethyl acetate, ethyl lactate, n-butyl acetate, and/or butyrolactone; aromatic compounds such as benzene, xylene, and/or toluene; or any combination thereof, without being limited thereto.

In some example embodiments, the developer may further include an organic compound including an acid group. For instance, the developer may include acetic acid, propionic acid, terephthalic acid, lactic acid, tartaric acid, or glycol acid, without being limited thereto.

As described with reference to FIG. 2C, a difference in solubility in the developer between the first area 132 of the photoresist film 130, which is exposed, and the second area 134 of the photoresist film 130, which is not exposed, may be increased. Thus, the first area 132 may not be removed but remain as it is while the second area 134 is being removed by developing the photoresist film 130 during the process of FIG. 2D. Accordingly, after the photoresist film 130 is developed, residue defects, such as a footing phenomenon, may not occur, and the photoresist pattern 130P may obtain a vertical sidewall profile. As described above, by improving the sidewall profile of the photoresist pattern 130P, when the feature layer 110 is processed using the photoresist pattern 130P, a CD of an intended processing region may be precisely controlled in the feature layer 110, thereby improving the quality (e.g., reduced process defects) in a pattern and/or device (e.g., integrated circuit device) including same. As described herein, an improved quality of a pattern and/or device may include improved accuracy and/or precision of conformance of structural dimensions of structures of the pattern formed in a method according to some example embodiments in relation to design dimensions of a design for such structures, such that the formed pattern and/or device conforms more closely to the design thereof.

In some example embodiments, after the photoresist pattern 130P is formed by developing the photoresist film 130 as described above with reference to FIG. 2D, a process of hard baking the obtained resultant structure may be further performed. Due to the hard bake process, unnecessary materials, such as the developer remaining on the resultant structure including the photoresist pattern 130P, may be removed. In addition, during the bake process performed in the process P50 of FIG. 1, which is described with reference to FIG. 2C, when the dissociation reaction of the organic ligand in the organometallic compound and the resulting additional condensation reaction are not sufficiently caused, additional reactions of the unreacted portions may be induced due to the hard bake process. Therefore, the hardness of the photoresist pattern 130P may be further increased due to the hard bake process.

The hard bake process may be performed at a temperature of about 50° C. to about 400° C. for about 10 seconds to about 150 seconds. For example, the hard bake process may be performed at a temperature of about 150° C. to about 250° C. for about 60 seconds to about 120 seconds, without being limited thereto.

Referring to FIGS. 1 and 2E, in process P70, the feature layer 110 may be processed by using the photoresist pattern 130P in the resultant structure of FIG. 2D.

To process the feature layer 110, various processes, such as at least one of a process of etching the feature layer 110 exposed by the openings OP of the photoresist pattern 130P, a process of implanting impurity ions into the feature layer 110, a process of forming an additional film on the feature layer 110 through the openings OP, or a process of modifying portions of the feature layer 110 through the openings OP, may be performed. FIG. 2E illustrates a process of forming a feature pattern 110P by etching the feature layer 110, which is exposed by the openings OP, as an example of processing the feature layer 110, but the inventive concepts are not limited thereto.

In some example embodiments, the process of forming the feature layer 110 may be omitted from the process described with reference to FIG. 2A. In some example embodiments, the substrate 100 may be processed using the photoresist pattern 130P instead of the process described with reference to the process P70 of FIG. 1 and FIG. 2E. For example, various processes, such as a process of etching a portion of the substrate 100 using the photoresist pattern 130P, a process of implanting impurity ions into a partial region of the substrate 100, a process of forming an additional film on the substrate 100 through the openings OP, and a process of modifying portions of the substrate 100 through the openings OP, may be performed.

Referring to FIG. 2F, the photoresist pattern 130P and the lower pattern 120P, which remain on the feature pattern 110P, may be removed from the resultant structure of FIG. 2E. The photoresist pattern 130P and the lower pattern 120P may be removed using an ashing process and a strip process.

In the method of manufacturing the IC device, which is described with reference to FIGS. 1 and 2A to 2F according to the inventive concepts, while energy is reduced by reducing a dose of first light having a relatively short wavelength, second light having a relatively long wavelength may be additionally introduced by using relatively low energy to induce the dissociation of a sufficient amount of organic ligand-metal bond and/or a cross-linking reaction between organic ligands. Thus, a difference in solubility in the developer between the exposed area and the non-exposed area of the photoresist film 130 may increase, and a CD distribution of the photoresist pattern 130P may improve. Accordingly, when a subsequent process is performed on the feature layer 110 and/or the substrate 100 using the photoresist pattern 130P, a dimensional precision may be improved by precisely controlling critical dimensions of processing regions or patterns to be formed on the feature layer 110 and/or the substrate 100. In addition, a CD distribution of patterns to be formed on the substrate 100 may be uniformly controlled, and the productivity of a process of manufacturing an IC device may be increased.

Experimental examples including specific Example and Comparative example will now be presented for simplicity, but they are merely examples and not intended to limit the inventive concepts.

### Example 1

An organometallic compound (5 wt %) represented by the following Formula 2, a photosensitive additive (of which a molar ratio to the organometallic compound is 0.02) represented by the following Formula 3, and a residual amount of PGMEA were mixed to prepare Composition A.

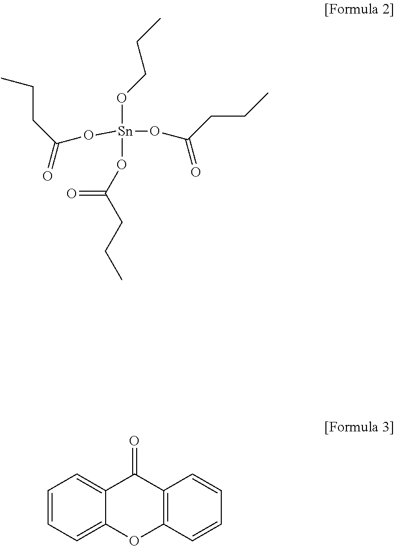 [SMILES: CCC[O][Sn]([O]C(=O)CCC)([O]C(=O)CCC)[O]C(=O)CCC ; O=c1c2ccccc2oc2ccccc12]

### Comparative Example 1

An organometallic compound (5 wt %) represented by Formula 2 and a residual amount of PGMEA were mixed to prepare Composition B.

### Evaluation Example

A lower film including a bottom anti-reflective coating (BARC) film was formed on a Si substrate and then coated with a composition to form a photoresist film.

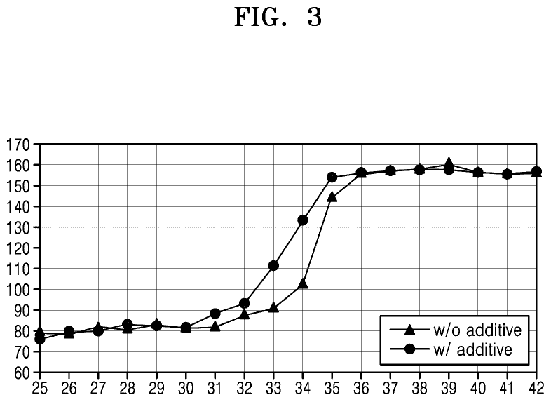

Afterwards, the photoresist film was baked at a temperature of about 110° C. for 60 seconds, then blanket exposed with i-line at 10 J, and blanket exposed with EUV at different doses. Thereafter, the photoresist film was baked at a temperature of about 160° C. for 60 seconds and treated with a developer including PGMEA and acetic acid, and a thickness of the remaining photoresist film was measured. Thus, a remaining film thickness relative to an EUV dose is shown in FIG. 3. Said process was repeated for both a photoresist film using Composition A according to Example 1 and a photoresist film formed using Composition B according to Comparative Example 1.

Referring to FIG. 3, it was seen that when (e.g., based on) the EUV dose was in a range of about 31 mJ/cm² to about 35 mJ/cm², a photoresist film formed using Composition A according to Example 1 (“w/additive”) was formed to a greater thickness than a photoresist film formed using Composition B according to Comparative Example 1 (“w/o additive”). Accordingly, it was inferred that Composition A according to Example 1 may form a cross-linked structure more easily by using a relatively small dose of EUV and form a photoresist film with a desired thickness by using relatively low energy, thereby improving the quality (e.g., reduced process defects, improved accuracy and/or precision of conformance of structural dimensions of structures formed in a method according to some example embodiments in relation to design dimensions of a design for such structures, etc.) in a pattern formed using the photoresist film and/or a device (e.g., integrated circuit device) including same. As described herein, an improved quality of a pattern and/or device may include improved accuracy and/or precision of conformance of structural dimensions of structures of the pattern formed in a method according to some example embodiments in relation to design dimensions of a design for such structures, such that the formed pattern and/or device conforms more closely to the design thereof.

While the inventive concepts have been particularly shown and described with reference to some example embodiments thereof, it will be understood that various changes in form and details may be made therein without departing from the spirit and scope of the following claims.

What is claimed is:

1. A photoresist composition comprising:
an organometallic compound including at least one metal-ligand bond and having an absorbance to first light, the at least one metal-ligand bond including a metal core and at least one organic ligand bonded to the metal core;
a photosensitive additive having an absorbance to second light having a longer wavelength than the first light; and
a solvent.

2. The photoresist composition of claim 1, wherein
the first light has a wavelength of about 10 nm to about 300 nm, and
the second light has a wavelength of about 300 nm to about 450 nm.

3. The photoresist composition of claim 1, wherein the photosensitive additive is configured to be excited by the second light to induce an oxidation-reduction reaction of the organometallic compound.

4. The photoresist composition of claim 3, wherein an energy density of the second light is about 10 mJ/cm² to about 20,000 mJ/cm².

5. The photoresist composition of claim 1, wherein a molar ratio of the photosensitive additive to the organometallic compound is in a range of about 0.01 to about 0.2.

6. The photoresist composition of claim 1, wherein the photosensitive additive comprises at least one of a thioxanthone-based compound, a benzophenone-based compound, an anthraquinone-based compound, a coumarin-based compound, a phenothiazine-based compound, a thiazoline-based compound, a rhodanine-based compound, an eosin-based compound, an erythrosine-based compound, an acridine-based compound, or a cyanine-based compound.

7. The photoresist composition of claim 1, wherein the photosensitive additive comprises at least one selected from compounds having structures represented by the following Formulas:

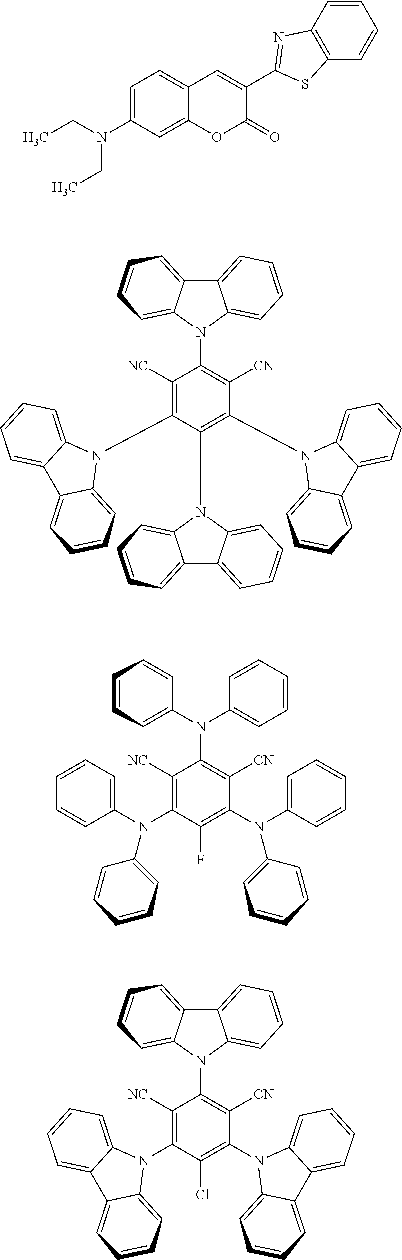

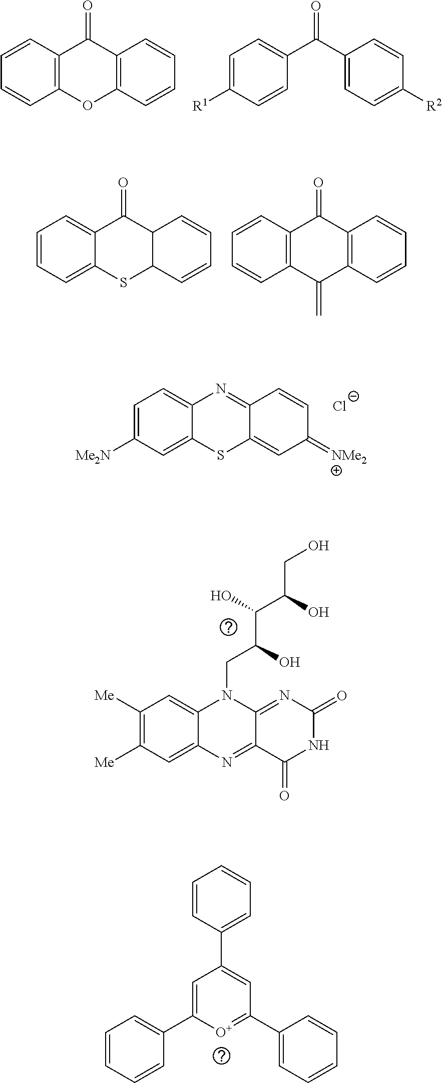

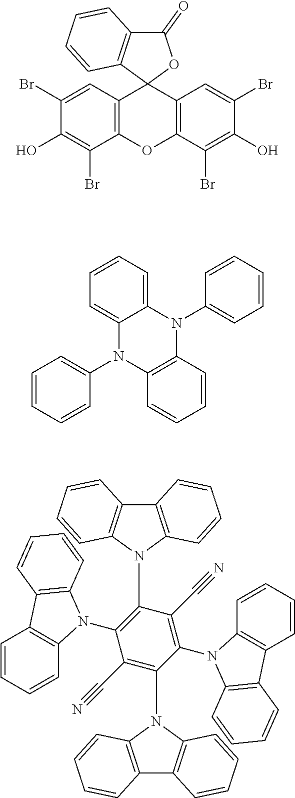 [SMILES: O=C1OC2(c3ccccc31)c1cc(Br)c(O)c(Br)c1Oc1c2cc(Br)c(O)c1Br ; c1ccc(N2c3ccccc3N(c3ccccc3)c3ccccc32)cc1 ; N#Cc1c(-n2c3ccccc3c3ccccc32)c(-n2c3ccccc3c3ccccc32)c(C#N)c(-n2c3ccccc3c3ccccc32)c1-n1c2ccccc2c2ccccc21]

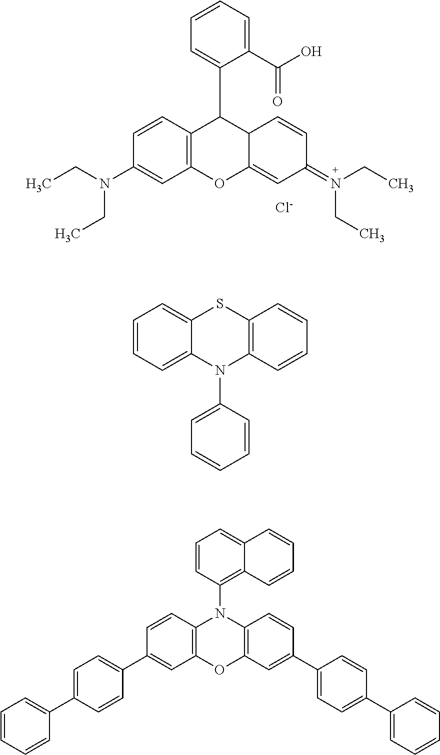

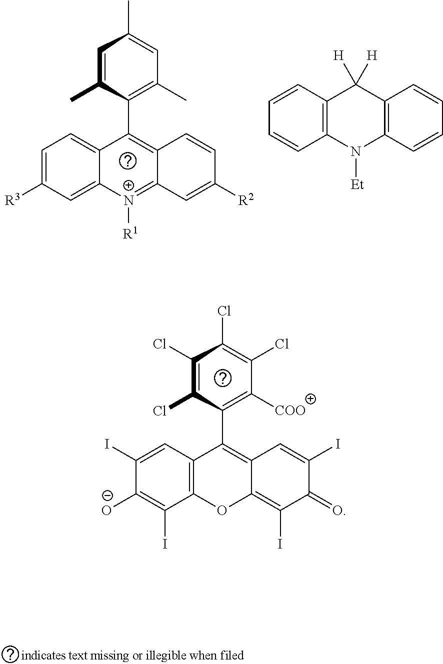

8. The photoresist composition of claim 1, wherein the metal core comprises at least one metal element selected from tin (Sn), antimony (Sb), indium (In), bismuth (Bi), silver (Ag), tellurium (Te), gold (Au), lead (Pb), zinc (Zn), titanium (Ti), hafnium (Hf), zirconium (Zr), aluminum (Al), vanadium (V), chromium (Cr), cobalt (Co), nickel (Ni), copper (Cu), gallium (Ga), manganese (Mn), strontium (Sr), tungsten (W), cadmium (Cd), molybdenum (Mo), tantalum (Ta), niobium (Nb), cesium (Cs), barium (Ba), lanthanum (La), cerium (Ce), and iron (Fe).

9. The photoresist composition of claim 1, wherein the organometallic compound comprises a compound represented by Formula 1:
M(X¹¹)ₐ(X¹²)_{b}(R¹¹)_{c}(R¹²)_{d} [Formula 1]
wherein, in Formula 1,
M is Sn, Sb, In, Bi, Ag, Te, Au, Pb, Zn, Ti, Hf, Zr, Al, V, Cr, Co, Ni, Cu, Ga, Mn, Sr, W, Cd, Mo, Ta, Nb, Cs, Ba, La, Ce, or Fe, and
each of X¹¹ and X¹² is independently a substituted or unsubstituted C1 to C30 aliphatic hydrocarbon group or a substituted or unsubstituted C6 to C30 aromatic hydrocarbon group, which includes at least one heteroatom and is coordinately bonded to M,
each of R¹¹ and R¹² is independently a substituted or unsubstituted C1 to C30 aliphatic hydrocarbon group or a substituted or unsubstituted C6 to C30 aromatic hydrocarbon group, which is covalently bonded to M,
each of a, b, c, and d is independently an integer of 0 to 4, and
c+d is an integer of 1 or more, and a+b+c+d is a positive integer of 4 or less.

10. The photoresist composition of claim 1, wherein an absorbance of the organometallic compound to the second light is less than the absorbance of the organometallic compound to the first light.

11. A photoresist composition, comprising:
an organometallic compound including at least one metal-ligand bond and configured to dissociate the at least one metal-ligand bond based on absorbing first light having a wavelength of about 10 nm to about 300 nm, the at least one metal-ligand bond including a metal core and at least one organic ligand bonded to the metal core;
a photosensitive additive configured to be excited based on absorbing second light having a wavelength of about 300 nm to about 450 nm to induce an oxidation-reduction reaction of the organometallic compound; and
a solvent.

12. The photoresist composition of claim 11, wherein the organometallic compound is configured such that the at least one metal-ligand bond is dissociated due to the oxidation-reduction reaction.

13. The photoresist composition of claim 11, wherein the organometallic compound comprises a compound represented by Formula 1:
M(X¹¹)ₐ(X¹²)_{b}(R¹¹)_{c}(R¹²)_{d} [Formula 1]
wherein, in Formula 1,
M is tin (Sn), antimony (Sb), indium (In), bismuth (Bi), silver (Ag), tellurium (Te), gold (Au), lead (Pb), zinc (Zn), titanium (Ti), hafnium (Hf), zirconium (Zr), aluminum (Al), vanadium (V), chromium (Cr), cobalt (Co), nickel (Ni), copper (Cu), gallium (Ga), manganese (Mn), strontium (Sr), tungsten (W), cadmium (Cd), molybdenum (Mo), tantalum (Ta), niobium (Nb), cesium (Cs), barium (Ba), lanthanum (La), cerium (Ce), or iron (Fe),
each of X¹¹ and X¹² is independently a substituted or unsubstituted C1 to C30 aliphatic hydrocarbon group or a substituted or unsubstituted C6 to C30 aromatic hydrocarbon group, which includes at least one heteroatom of S, O, and N and is coordinately bonded to M,
each of R¹¹ and R¹² is independently a substituted or unsubstituted C1 to C30 aliphatic hydrocarbon group or a substituted or unsubstituted C6 to C30 aromatic hydrocarbon group, which is covalently bonded to M,
each of a, b, c, and d is independently an integer of 0 to 4, and
c+d is an integer of 1 or more, and a+b+c+d is a positive integer of 4 or less.

14. The photoresist composition of claim 11, wherein an energy density of the second light is about 0.1 mJ/cm² to about 50 mJ/cm².

15. The photoresist composition of claim 11, wherein a molar ratio of the photosensitive additive to the organometallic compound is in a range of about 0.01 to about 0.2.

16. A method of manufacturing an integrated circuit device, the method comprising:
forming a photoresist film on a substrate based on using a photoresist composition including an organometallic compound and a photosensitive additive, the organometallic compound including a metal core and at least one metal-ligand bond bonded to the metal core, wherein the organometallic compound has a sensitivity to first light and the photosensitive additive has a sensitivity to second light;
exposing a first area of the photoresist film to the first light;
exposing an entire area of the photoresist film to the second light;
forming a network of metal structures in the first area based on baking the photoresist film; and
forming a photoresist pattern based on developing the photoresist film in which the network of the metal structures is formed, the photoresist pattern including the network of the metal structures,
wherein the first light has a wavelength of about 10 nm to about 300 nm, and the second light has a wavelength of about 300 nm to about 450 nm.

17. The method of claim 16, wherein the exposing of the entire area of the photoresist film to the second light is performed before the exposing of the first area to the first light.

18. The method of claim 17, further comprising baking the photoresist film subsequently to the exposing of the entire area of the photoresist film to the second light and before the exposing of the first area to the first light.

19. The method of claim 16, further comprising exposing the entire area of the photoresist film to the second light before the exposing of the first area to the first light.

20. The method of claim 16, wherein the photosensitive additive is excited by the second light and induces an oxidation-reduction reaction of the organometallic compound.
